(19) United States
(12) Patent Application Publication
(10) Pub. No.: US 2012/0134504 A1
(43) Pub. Date: May 31, 2012

(54) CHAOTIC PULSE TRAIN SYNTHESIZER

(75) Inventor: Nathaniel Napoletano, Akron, OH (US)

(73) Assignee: Lockheed Martin Corporation, Bethesda, MD (US)

(21) Appl. No.: 13/115,257

(22) Filed: May 25, 2011

Related U.S. Application Data
(60) Provisional application No. 61/417,331, filed on Nov. 26, 2010.

(51) Int. Cl. H03G 3/00

(52) U.S. Cl. 381/61

(57) ABSTRACT

A system includes a pulse generator to generate a repeating pulse train including at least two pulses per cycle of the pulse train. A feedback loop creates chaos inducing components from each pulse of a cycle and adds the chaos inducing components to at least two pulses of a next cycle of the repeating pulse train to provide a signal representative of sound made by a simulated device.

### RELATED APPLICATION

This application claims priority to U.S. Provisional Application Ser. No. 61/417,331 (entitled CHAOTIC PULSE TRAIN SYNTHESIZER, filed Nov. 26, 2010) which is incorporated herein by reference.

### BACKGROUND

The art and science of creating an audible experience that is intended to represent an event or state of ambiance for a listener is called sound design. Sound design has become a necessary activity in the theater and cinema and is no less important in simulation and virtual gaming.

A sound designer will find that they spend much of their time listening intently to example recordings of sound effects intended for simulation and comparing them to his synthesized new sounds in their simulated context. Unlike the simple tones used in headsets to alert pilots and soldiers of emergent conditions, natural environmental sounds have qualities that make them unique, unmistakable and challenging to duplicate. A tone without variation is produced by, what engineers call, a continuous waveform. Almost nothing in the environment produces a continuous waveform including birds, machines, rolling tires, automatic guns and people. Real world entities like these, with sufficient complexity to emit a time-varying, non-repeating waveforms are called natural systems.

In the case of vehicles and machines, fuel combustion, movements, air flow noise and rattling component parts cause their sound to change continually as the entity continues to emit sound. Often parameters being introduced into the physical system such as more fuel into an engine will cause the entity to transition into different operational modes with different but related sound, in the same way that more air or a tighter embouchure will change the timbre, but not necessarily the pitch, of a trumpet. Musicians refer to these variations as articulations. These variations are created by higher pitched sounds within the sound called harmonics. Unlike a continuous wave, the harmonic content of a natural sound will change over time.

When an engine or a machine starts up, a vehicle begins to move, or a bow begins to travel across a violin string, vibrating parts break into oscillation and change modes several times before stabilizing somewhat. These changing modes produce changing harmonics, Musicians refer to the starting sound as the attack and in many cases it is the most distinguishing part of the sound.

The human auditory system, and apparently that of many animals, becomes trained to track the time varying harmonic structure produced by a natural system's varying vibrational modes. Listeners with normal hearing are extremely skilled at detecting how sound patterns develop over time. In fact the situation is such that no existing physical modeling computer simulation gets it completely right. And despite the advanced state of some software tools, there is currently no automated method in existence for analyzing an environmental sound that rivals attentive listening. This is what makes sound modeling an art and makes natural aural effects challenging to replicate with software.

Sounds produced by trucks using reciprocating piston engines, tanks, rotary wing aircraft and automatic guns are simulated with the use of non-linear aural pulse trains (NAPT). A major disadvantage of existing sound generation methods used to simulate NAPT in immersive virtual environments is that none provide all of the desired aural fidelity and dynamic control features simultaneously. These features provide cues that play a key role in informing a student about his situational threats and support resources. Abstract synthesis techniques allow controlled timbre change correlated with the simulated load or acceleration of the virtual vehicle, but lack fidelity. Wavetable synthesis provides fidelity while allowing little controllability.

### SUMMARY

A system includes a pulse generator to generate a repeating pulse train including at least two pulses per cycle of the pulse train. A feedback loop creates chaos inducing components from each pulse of a cycle and adds the chaos inducing components to at least two pulses of a next cycle of the repeating pulse train to provide a signal representative of sound made by a simulated device.

### BRIEF DESCRIPTION OF THE DRAWINGS

FIG. 1 is a block diagram of a sound simulation system according to an example embodiment.

FIG. 2 is a diagram of an acoustical waveform produced by a six cylinder engine according to an example embodiment.

FIG. 3 is a diagram of an acoustical waveform produced by an eight cylinder engine according to an example embodiment.

FIG. 4 is a diagram of a model of an exhaust system according to an example embodiment.

FIG. 5 is a block diagram of a six cylinder truck chaotic pulse train synthesizer (CPTS) simulation system according to an example embodiment.

FIG. 6 is a diagram of an acoustical waveform produced by rotating rotors according to an example embodiment.

FIG. 7 is a block diagram of a rotary winged aircraft sound simulation system according to an example embodiment.

FIG. 8 is a diagram of an acoustical waveform produced by an M61 gun according to an example embodiment.

FIG. 9 is a block diagram of a typical computer system used to provide simulation modules according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

The functions or algorithms described herein may be implemented in software or a combination of software and human implemented procedures in one embodiment. The software may consist of computer executable instructions stored on a tangible computer readable media such as memory or other type of storage devices. The term “computer readable media” is also used to represent any means by which the computer readable instructions may be received by the computer, such as by different forms of wired or wireless transmissions. Further, such functions correspond to modules, which are software, hardware, firmware or any combination thereof. Multiple functions may be performed in one or more modules as desired, and the embodiments described are merely examples. The software may be executed on a digital signal processor, application specific integrated circuit (ASIC), microprocessor, or other type of processor operating on a computer system, such as a personal computer, server or other computer system.

The type of sound produced by piston engines and automatic guns shares a common characteristic. They disturb the air with a series of small explosions that propagate in a particular type of wave that engineers call a pulse train. Helicopter rotors also produce pulse trains by compressing air with powerful sweeps of their rotating wings. In all of the following examples we will be examining the pulse trains using the graphical depiction of a sound wave, something engineers call an acoustical waveform. This picture is a recording, made with a microphone, of the sound pressure wave emitted from the machine under study. The sound pressure wave is plotted against time, like the grooves in a vinyl record, and is often referred to as a time-domain plot to differentiate it from many more sophisticated types of displays that engineers use to visualize sound. For analyzing pulse trains, the acoustical waveform is superior because it captures many subtleties present in each pulse and allows us to count and categorize them.

An important component of natural systems is chaos, and chaos is responsible for the natural and realistic sound they produce. Chaos, in this context, has a precise mathematical meaning that diverges from its common usage suggesting complete disorder. Natural systems exhibit chaos because parts of the system retain vibrations and pressure waves from activities in the recent past that affect the current state. Mathematicians characterize this historic information as non-linear and its presence causes changes in the states of a machine that are both regular and irregular. Mathematicians call the regular states that come and go in a natural system strange attractors. The regular and irregular state changes are heard by the listener and become an important cue to separate an authentic natural sound from one that was simulated with a overly simple model. (Note: in this context, the overused term “non-linear” refers to mathematical factors that carry a history from a signal and lead to chaotic behavior. This is a different meaning than a future mention of non-linear in reference to a distorted transfer function.) Pulsating machines, such as trucks using reciprocating piston engines, tanks, rotary wing aircraft and automatic guns produce Non-linear Aural Pulse Trains (NAPT) because of their chaotic behavior.

When wavetable synthesis is inadequate, audio engineers have a huge legacy of sound synthesis techniques to call upon. One such technique is physical modeling. The advantage of physical modeling is that the components and parameters involved are easily understood since they have real world counterparts. Practically all sound synthesis techniques, other than physical modeling, are commonly referred to as abstract sound synthesis due to the fact that operational modules within the synthesis process do not have direct counterparts in the physical world. Physical modeling can have a level of abstraction that can range from simple waveguide models to direct simulations where every sound producing part of a machine has a mathematical representation executed within the model.

Physical modeling can also be central processing unit (CPU) intensive. This is the reason why physical modeling was overshadowed by abstract synthesis techniques and remained in the university labs until fast modern computers made abstract synthesis practical for training system use. In spite of increased processing power and speed, a sound designer should consider efficiency when modeling a sound producing entity or else a detailed model could fully occupy several of the CPUs in a multi-CPU computer. This situation becomes unwelcome when several sound producing entities are operated concurrently. For this reason several standard and efficient techniques have been invented with Digital Waveguide Modeling (DWM) enjoying the most widespread usage.

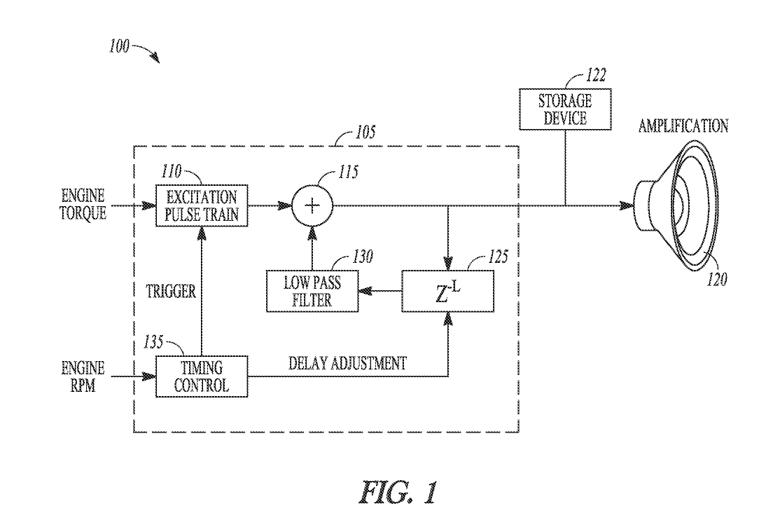

A sound simulation system shown generally at 100 in FIG. 1 models aural pulse trains corresponding to sounds produced by equipment such as trucks using reciprocating piston engines, tanks, rotary wing aircraft and automatic guns. In one embodiment, the system 100 includes a Chaotic Pulse Train Synthesizer(CPTS) indicated by broken line 105. An excitation pulse generator 110 provides a pulse train that is delivered to CPTS 105 through a summing junction 115. The excitation pulse is delivered to a loudspeaker 120 or storage device 122 as the first sound component to be heard. The loudspeaker 120 or storage device 122 may be integrated with the CPTS 105, or may be external to and receive an output from CPTS 105 in various embodiments. The pulse is also fed back through a delay line 125 and filter 130 into the summing junction 115. In one embodiment, filter 130 includes a low pass filter. The delayed and filtered version of two or more original pulses is referred to as a looping series of pulses and becomes the next sound component. The looping series is subsequently delayed and filtered again as it continues to loop. With each loop, the looping series is delivered from CPTS 105 to the loudspeaker 120 or storage device 122, or both. The looping series continues to loop as long as the simulated engine is running.

Typically, the period of a delay line is adjusted to correspond to two or more pulses, depending on the number of pulses created by the equipment being simulated so that the looping series is always synchronized with the new excitation pulses. For a two cycle engine, the delay line 125 is adjusted to correspond to a time allowing looping of both pulses together. For a six cylinder engine, that delay line 125 may be adjusted to correspond to a time allowing looping of six pulses corresponding to the firing of each of the six cylinders. The number of pulses in a cycle of the pulse train corresponds to length of the cycle of pulses of the device being simulated. In one embodiment, a timing controller 135 such as a stored software object, receives timing information such as rotation per minute (RPM) information for the equipment being simulated, and is coupled to adjust the delay line 125 and provide a trigger for the pulse generator 110. The pulse generator may also receive torque information corresponding to the equipment being simulated to control the pulses that are being generated to correspond to the torque on the equipment.

The RPM of the engine simulation also depends on the period of the delay line but may be continuously adjusted as the simulated engine revs. For this reason, adjustments to the delay line period are made synchronously in one embodiment with the emerging pulse stream, taking care not to drop data chunks or introduce silent memory blocks into the center of pulses.

CPTS 105 uses a delay time that corresponds to the equipment's period. The delay time is lengthened beyond the single pulse to accommodate a complete set of pulses for each cylinder of the engine type. For a four cycle diesel or gasoline engine, typical of modern trucks and buses, each period of the delay line will contain or circulate a complete set of cylinder firing pulses for two complete revolutions of the engine. A complete set would equal the number of cylinders used for that engine type (six cylinders for a six cylinder engine). Two cycle engines, used in railroad locomotion and marine propulsion, can also be simulated with this method using a complete set of cylinder firing pulses for one complete revolution of the engine.

The CPTS 105 implements an algorithm that performs the two most complex tasks required to generate the non-linear aural pulse train. Because the excitation pulses are emerging from a recycling delay line system containing the correct number of pulses for that engine, the natural rhythm for that engine type emerges. Chaotic changes to the pulse train also occur naturally and without any specific signal processing because rhythmic structures that emerge remain present only temporarily. This chaotic behavior produces a high fidelity and realistic output signal. Emergent rhythmic structures eventually decay as their energy is consumed by the filter 130 and new structures emerge to replace them. Since the chaotic components to the pulse train emerge from non-linear energy circulating around in a CPTS feedback loop, the chaotic components are provided without consuming processing resources provided that the filter 130 is adequately adjusted. This activity is similar to the type of chaos desired, but has no correlation with the chaotic hops from a real world engine pulse stream. In some embodiments, the adjustment may be made by ear. As is often the case in sound modeling, at least one parameter may be tweaked until it sounds as much like the sound generated by a real engine or other equipment as desired.

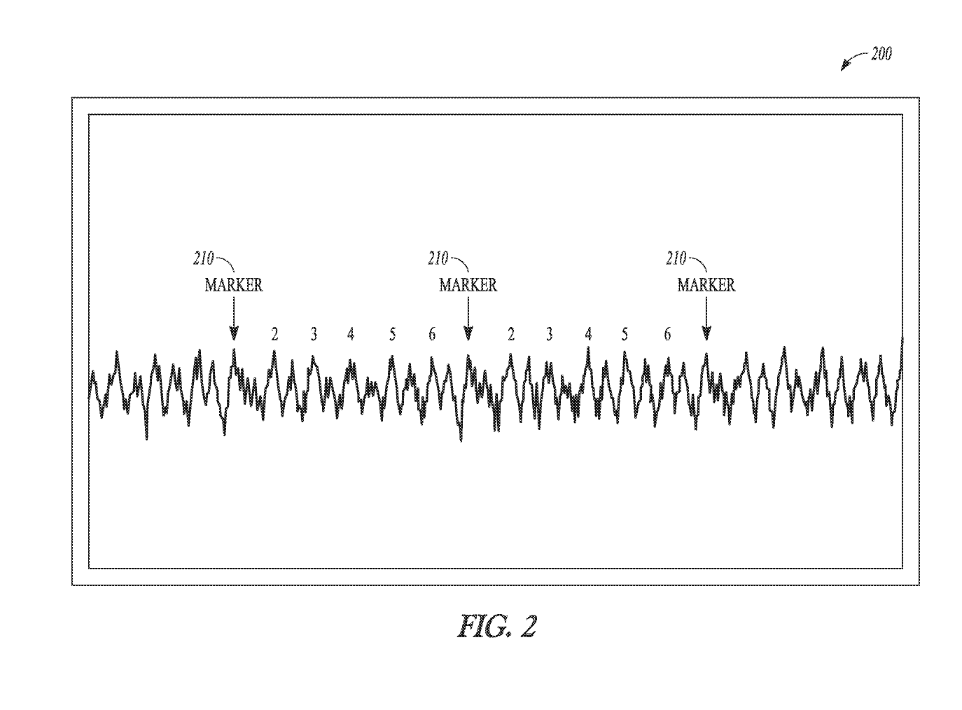

FIG. 2 shows an example acoustical waveform 200 produced by an idling six-cylinder dump truck. The sound pressure wave's displacement is plotted in the vertical axis against time. The waveform illustrates both chaotic and rhythmic behaviors. There is a regular pattern exhibited in the pulse train that repeats in groupings of six pulses, referred to as the period of the pulse train. The groupings of six pulses correlates to the number of cylinders. An easily identified marker 210 for this rhythm is a cylinder that seems to ring with more tenacious high frequency energy than the other cylinders after each firing. Markers, if present, may take an almost unlimited variety of forms. The chaotic behavior is evident from the variation between the six pulse groupings. Noticeable pulses between actual firings (numbered 2 through 6) are echoes from a street.

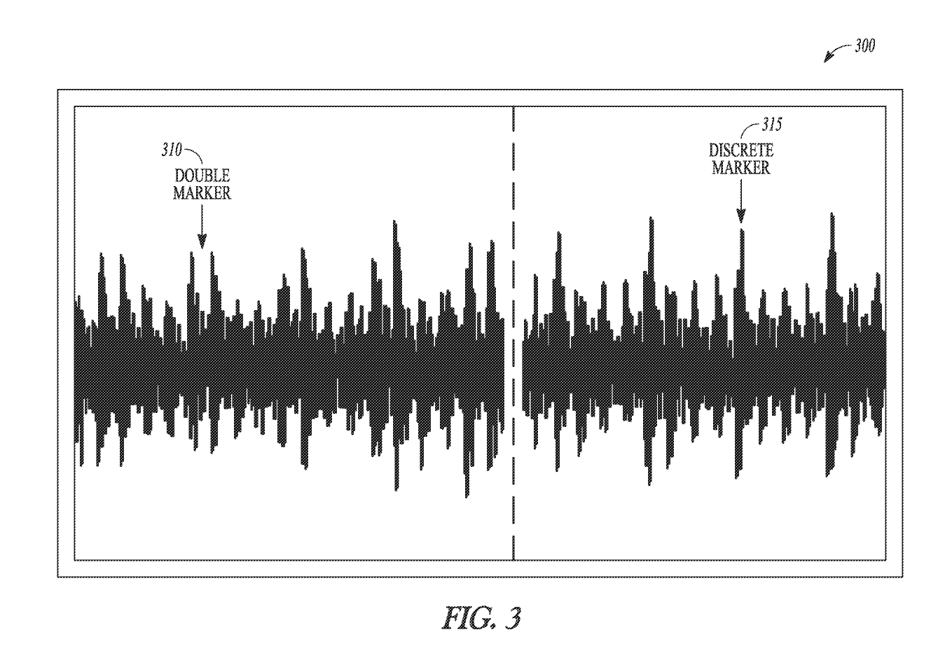

The effects of chaos are even more perceptible when one considers the occasional transformations that occur in what is perceived to be the markers themselves. The transformations may occur at irregular intervals in an idling engine. In an example waveform depicted in FIG. 3 at 300, an eight cylinder engine idles for several seconds. The engines advancement may be tracked by a series of doublet markers 310 occurring every four pulses. Without any obvious stimulus to the system, a brief transition takes place and the engine settles into a brief mode where lone strong pulses 315 replace the doublets as illustrated on the right side of the waveform, before evolving again.

The change may be the result of nonlinear pressure waves in the manifolds or fuel lines. It may also be something as simple as the engine rocking on its mounts or the aggregate effect of many non-linear factors. However, it is unnecessary to probe into the physics of this effect since the CPTS algorithm will simulate this type of chaos effortlessly and the sonic effect is similar.

An interesting change to the sound of a piston engine takes place as a driver begins to accelerate. The pulse rate emanating from the engine is directly related to the engine's RPM. When the driver intends to accelerate the driver steps on the accelerator pedal, opening a throttle valve that allows more air and fuel into each cylinder. The engine's RPM usually begins to rise, although this may not always be the case as with a generator being placed under a load. But before the engine's RPM changes, there is an almost instantaneous change to the pulse train's articulation. Each pulse becomes louder, more distinct and aggressive sounding as the engine roars. The rise and fall time of each pulse becomes steeper with more harmonic content. So a proper simulation of vehicle's piston engine will require that some type of a torque or load and throttle inputs from the vehicle's operational simulation be used to modify the CPTS excitation pulse train.

Since direct simulation is too complex for real-time simulation, without CPTS synthesis, other options for simulating this rather complex sound are limited to wavetable and subtractive synthesis. Wavetable synthesis will not provide the control necessary to simulate acceleration and deceleration. Subtractive synthesis involves generating harmonically rich pulses and filtering them to match the character of a running engine. The resulting pulse train, if used directly, lacks the realism of the chaotic sound component.

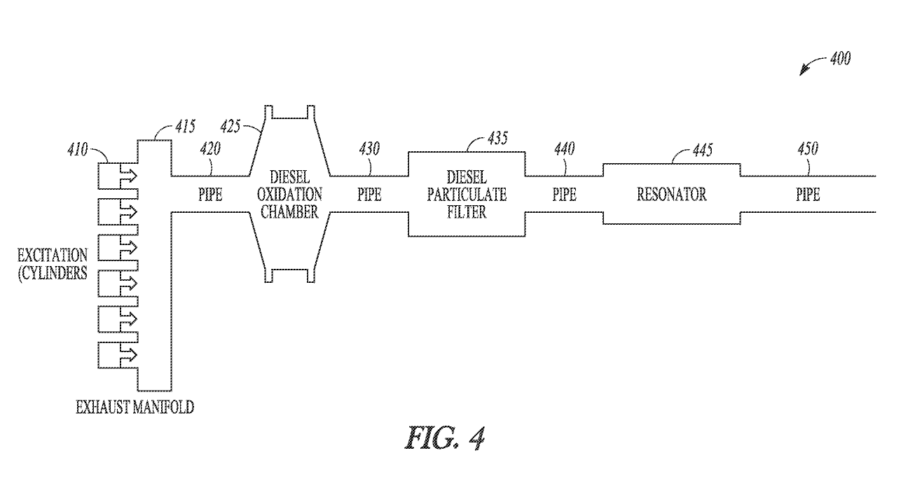

In one embodiment, an engine simulation utilizes further sound modeling components for simulating an exhaust system as shown in FIG. 4 at 400 with sound producing or excitation cylinders indicated at 410. Element 410 receives the output of CPTS 105. The pulse train produced by the object referenced as 410 in one embodiment is a continuous series (sequential set) of X pulses wherein X represents the number of cylinders. The X pulses shown represent 6 cylinders. However, the number of pulses may be variable corresponding to the cyclic nature of the element being synthesized. The remainder of the engine simulation is a straight-forward modeling of the exhaust system acoustics. The exhaust system may be modeled as several resonant cavities connected by pipes of varying lengths. This type of modeling is classic and simple to implement in software.

An exhaust manifold 415 is shown with the excitation source or cylinders corresponding to the CPTS generated non-linear aural pulse train. The manifold 415 is coupled via a pipe 420 to a diesel oxidation chamber 425, which is in turn coupled via a pipe 430 to a diesel particulate filter 435. The filter 435 is coupled via a pipe 440 to a resonator 445, and finally to an exhaust pipe 450. Each of these elements may be modeled by wavetable synthesis or other types of synthesis in further embodiments, modifying the sound corresponding to the non-linear aural pulse train.

Other sound components, auxiliary sounds that may be generated with wavetable synthesis, may be added to the composite sound in order to produce a useful vehicle simulation. Typical additive sounds include tire noise, ground rumble and brakes, but may also include noise due to air intake, pneumatics, fan belts, an engine turbocharger, frame and body part rattle, etc.

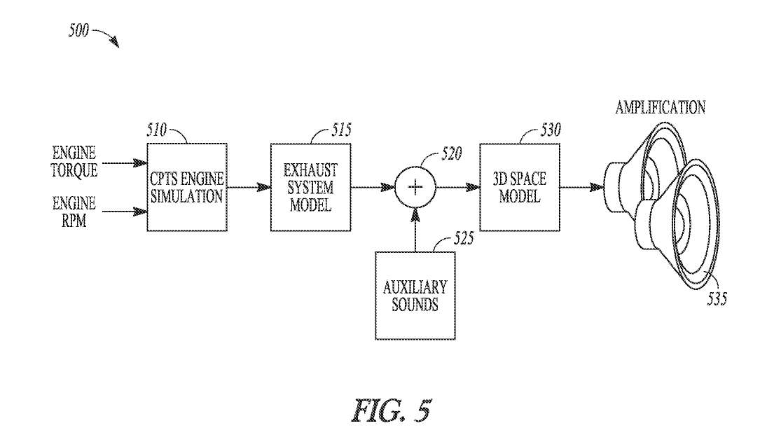

Even if all of the components described above are perfectly implemented, the acoustical truck model would still sound artificial. Unless the truck is permanently parked directly in front of a listener, it needs to be positioned in 3-Dimensional (3D) space by modeling the resulting sound field as illustrated in FIG. 5 at 500. This step is may be done with every entity in the integrated circuit (IC) gaming area, and so some type of accelerated 3D sound processing is assumed to exist on the simulation platform. With all of the cumulative sounds and spatial positioning taken into consideration, FIG. 5 shows a block diagram of a six cylinder truck CPTS simulation system 500 placed in 3D space. System 500 includes a CPTS engine 510 (which may be the same as CPTS 105 in one embodiment) providing an audio pulse train to an exhaust system model 515, corresponding to exhaust system 400 in one embodiment. An output of the exhaust system model is fed into an optional summing node 520. If included, summing node 520 also receives auxiliary sounds 525, which are summed with the output of the exhaust system model 515 and provided to a three dimensional space model 530 in one embodiment to model sound in three dimensional space and provide it for amplification at 535 via one or more speakers, or optionally storage such as by a storage device 122 in FIG. 1.

As mentioned earlier, there are several types of NAPT sounds, in addition to piston engines, that can be effectively modeled with CPTS synthesis. A very useful example in the world of IC simulation is the rotary winged aircraft, including helicopters.

When listening to helicopter recordings from the field, one is struck by how important 3D spatial positioning and wave propagation effects are to a rotary winged aircraft sound effect. Unless the craft is within 1000 ft. and in direct ear-shot, the overwhelming sounds one hears are reflections from the terrain and air layers. Within a three minute flyby, there are times when the sound produced by a rotor shakes the ground and other times when the rotor sound seems to vanish beneath the turbine engine's faint whine. There also seems to be every variation between the two extremes. To limit 3D wave propagation complexity, a section of sound is considered where the helicopter is in close proximity and the direct wave dominates.

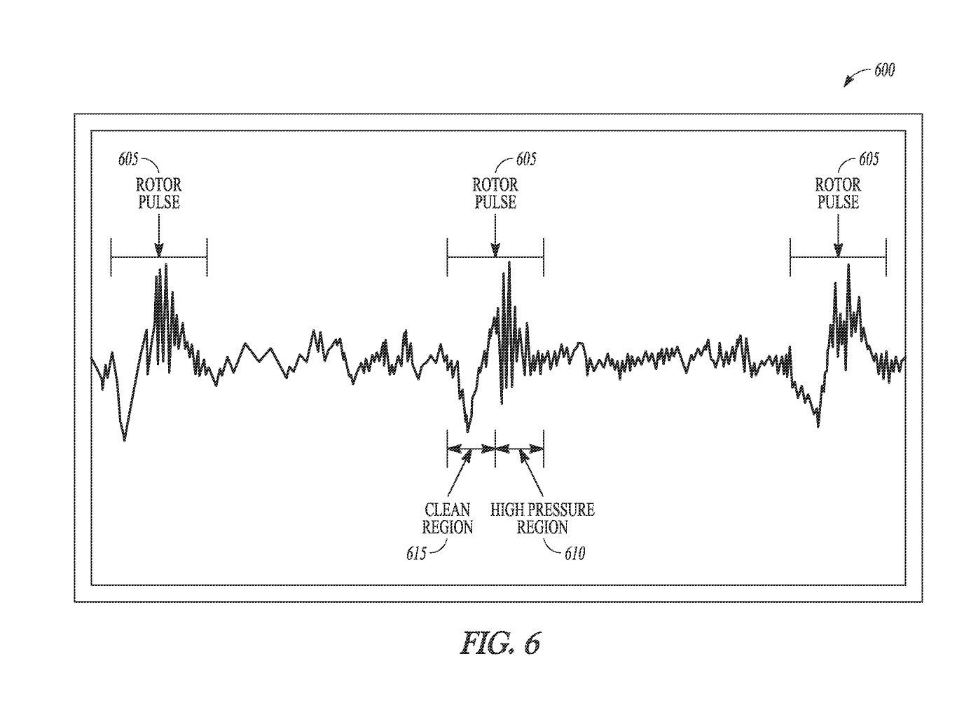

FIG. 6 shows an acoustical waveform at 600 produced by a U.S. Army Bell UH-1 Iroquois flying by at close range. While listening to the sound recording one hears the effect of the rotor's pulse train 605 and the continuous whine of the jet engine. A careful listening reveals that there is strong dissimilarity between alternating pulses like the right and left hand of a drummer creating sort of a “Pu-Ta-Pu-Ta” effect. This makes sense from the standpoint that there are two rotary wings alternately making this effect. The sound produced from the two wings does not appear to be identical. The effect suggests that the rotor sound should be modeled by setting the period of the CPTS delay line large enough to accommodate two rotor pulses, allowing the rhythm of two cycles to emerge.

Another feature that can be observed in the waveform is that the rotor's pulse train causes a severe modulation of the turbine engine whine. The modulation is remarkable in that it goes beyond the expected Doppler distortion and creates an amplitude modulation. FIG. 6 shows this apparent effect where the high pressure 610, dense air created each time the rotor passes overhead supports good propagation of the high frequency turbine sound. This effects is preceded by a “clean” 615 (reduced in high frequency energy) period where the rarefied air during a relaxation period stifles the turbine whine.

This means that a reasonable helicopter simulation may be obtained by merging a standard jet engine simulation with a simulated rotor pulse train through a simple non-linear air model. In this context, the term “non-linear” refers to a transfer function that deviates from a straight line or whose output is not proportional to its input, as air under the influence of a strong pressure wave. This is a different meaning than the earlier use of non-linear in reference to chaotic behavior.

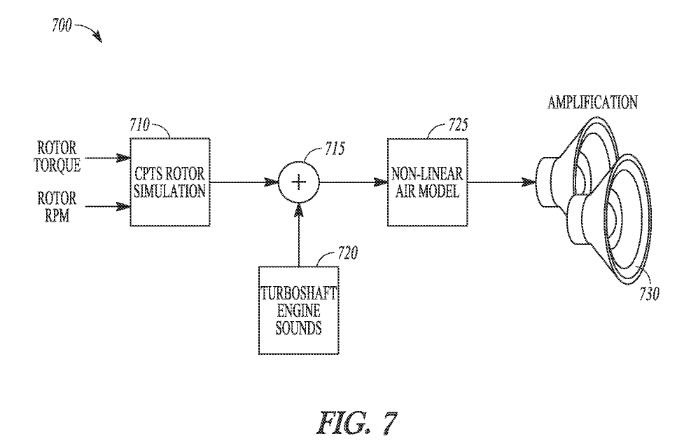

FIG. 7 is a block diagram of a rotary winged aircraft sound simulation system at 700. The system includes a pulse generator 710 corresponding to rotor simulation. Pulse generator 710 is the same as CPTS 105 in one embodiment. A pulse train from the generator 710 is summed at 715 with sound generated from a turbo shaft engine sound generator 720 and provided to a non-linear mixer air model at 725 before being provided for amplification at 730 via one or more speakers or storage such as by a storage device 122 shown in FIG. 1. The excitation pulse generator 710 for the rotary wing produces a low frequency pulse (subsonic), unlike the piston pulse simulation that was rich in broad spectrum content. The CPTS delay line, in this case, has a period adjusted to the size of two pulses in order to create the effect of the two rotary wings. What was the exhaust simulation in the piston engine model can be reduced to a simple low pass filter or removed entirely if the CPTS Rotor Simulation can be made to produce accurate renditions of the rotor effect.

The non-linear mixer 725 may be modeled in different ways and several classes of transfer function seem to produce adequate results. For one embodiment utilized in testing, an addition of the properly scaled input signals may be followed by a distortion algorithm. The transfer function, f(x), of the distortion algorithm is defined by Eq. 1 below. “x” is the input to the mixer 725. Many different functions that would have the effect of attenuating the turbine engine sound stream each time it was shoved into the non-linear region by the low frequency rotor pulse may be used to create a similar effect.

$$\begin{matrix}Distortion Function & \\ f ( x ) = \frac{x}{0.8 + {( 0.59 x )}^{2}} . & Equation 1\end{matrix}$$

Large, multi-barrel guns like those used in military aircraft present an audio profile similar to the piston engine, with some parametric differences. In one embodiment, a CPTS pulse train generator such as CPTS 105 may be used to simulate the sound of a rapid fire gatling-type gun. The generator is coupled to a storage device, such as storage device 122 or a loudspeaker 120 in various embodiments as shown in FIG. 1.

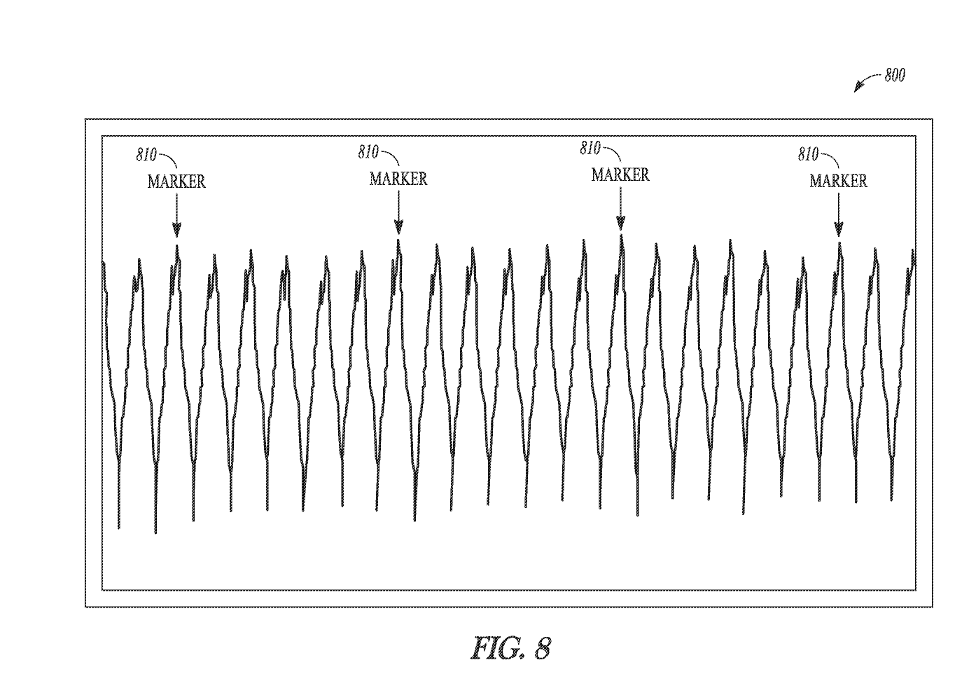

The General Electric M61 Vulcan cannon is a 6-barrel, 20 mm, electrically fired, rotating gun. It fires standard M50 ammunition at selectable rates up to 6,000 rounds per minute. FIG. 8 shows an acoustical waveform 800 produced by the M61 gun. A remnant effect of 6 barrels being fired in sequence is apparent from looking at the waveform. The marker 810, in this case, is the pulse that consistently stands taller than its neighbors. The appearance of the marker 810 is subtle, possibly due to the fact that the gun is made with precision, and the 6 barrel rhythm is inaudible for all practice purposes. The much more prominent effect is the chaotic undulations of the pulse train that make CPTS synthesis the optimal method for modeling this NAPT.

The CPTS automatic gun simulation takes the same form as the piston engine simulation, only the simulation parameters are changed to alter the sound. In this case, the gun has 6 barrels matching the number of cylinders from the piston engine example so that the delay line length remains unchanged. Since the automatic gun has no equivalent to the truck's exhaust system, a simple resonant filter can be used to shape the chaotic pulse train into timbre expected from a gun barrel.

As with vehicle simulation, the M61 gun has other sound attributes that are unrelated to CPTS synthesis, but whose implementation would be necessary to produce an accurately modeled simulation. One of these effects is the wind-up and wind-down effect. The M61 gun begins firing bullets before it has reached its target RPM and continues to fire a few off after the gunner releases the trigger. A listener can hear the gun's pitch rise when firing begins, not unlike a power lawn mower coming to full RPM after being started, and fall when firing ceases. Where to place the software object that simulates the gun wind-up and wind-down is a job for the systems engineer but the author anticipates that the environment simulation does not contain that level of detail and some type of control system belongs in the gun simulation software.

Many other types of sounds like pistons and rotors may be simulated using the modified CPTS algorithm having delay lengths corresponding to multiple pulses. While adjusting the system parameters of the CPTS gun simulation, the simulation begins to sound a lot like a pneumatic concrete hammer. Such sounds demonstrate the versatility of the CPTS sound generator.

The functional components of the CPTS concrete hammer simulation are the same as that of the piston engine. The two major differences are in the pulse train generator's delay line and the exhaust simulation. The delay line, in this case, has a period adjusted to the size of one pulse because the same bit hits the concrete with each strike and there should be no rhythmic component to the strikes, just the chaotic component. The adjustments to the exhaust system simulation are necessary to reduce its effect since there is no effective aural filtering between the tool and a close by listener. Introduction of'some resonant filters in the high frequency range should also be used to create the effects of the ringing steel bit striking concrete and the pneumatic exhaust puffs.

Various embodiments described may provide high fidelity sound simulation of vehicles and machinery that produce rhythmic, chaotic pulse trains. CPTS synthesis provides the optimal mechanism for physically modeling those machines. Some advantages of embodiments utilizing multi-pulse CPTS algorithms over wavetable, subtractive and detailed physical modeling synthesis are lower CPU usage and a more predictable and cost effective programming effort. The CPTS algorithm adds, simultaneously, the rhythmic and chaotic components to an audio pulse train creating a sense of realism that would be costly to obtain with detailed physical modeling and possibly unachievable with other traditional methods of sound synthesis.

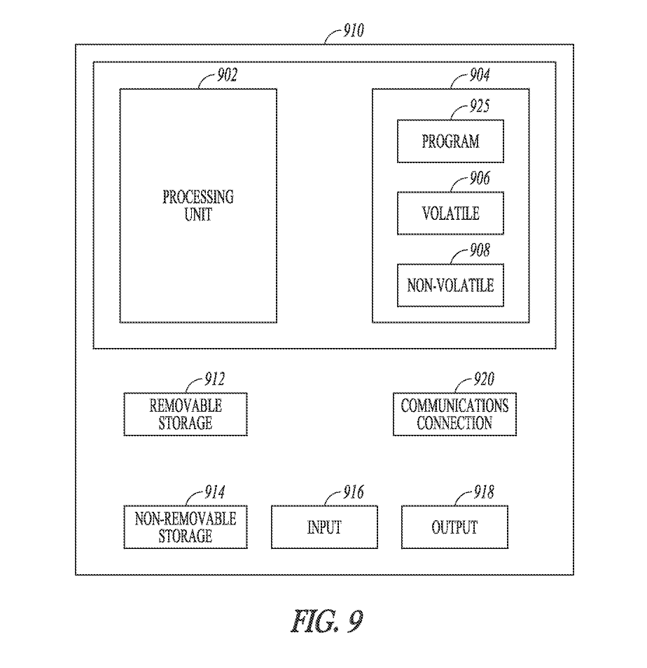

A block diagram of a computer system that executes programming for performing the above algorithm is shown in FIG. 9. A general computing device in the form of a computer 910, may include a processing unit 902, memory 904, removable storage 912, and non-removable storage 914. Memory 904 may include volatile memory 906 and non-volatile memory 908. Computer 910 may include—or have access to a computing environment that includes—a variety of computer-readable media, such as volatile memory 906 and non-volatile memory 908, removable storage 912 and non-removable storage 914. Computer storage includes random access memory (RAM), read only memory (ROM), erasable programmable read-only memory (EPROM) & electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage or other magnetic storage devices, or any other medium capable of storing computer-readable instructions. Computer 910 may include or have access to a computing environment that includes input 916, output 918, and a communication connection 920. The computer may operate in a networked environment using a communication connection to connect to one or more remote computers. The remote computer may include a personal computer (PC), server, router, network PC, a peer device or other common network node, or the like. The communication connection may include a Local Area Network (LAN), a Wide Area Network (WAN) or other networks.

Computer-readable instructions stored on a computer-readable medium are executable by the processing unit 902 of the computer 910. A hard drive, CD-ROM, and RAM are some examples of articles including a computer-readable medium.

1. A system comprising:
a pulse generator to generate a repeating pulse train including at least two pulses per cycle of the pulse train; and
a feedback loop creating chaos inducing components from each pulse of a cycle and adding the chaos inducing components to at least two pulses of a next cycle of the repeating pulse train to provide a signal representative of sound made by a simulated device.

2. The system of claim 1 wherein the feedback loop comprises:
a summing junction coupled to the pulse generator;
a delay line adapted to receive the pulse train from the summing junction and to provide a delay corresponding to the cycle of the pulse train; and
a filter coupled to receive the pulse train from the delay line, attenuate the pulse train, and provide the chaos inducing components to the summing junction.

3. The system of claim 2 and further comprising a speaker coupled to the summing junction to convert the signal to sound.

4. The system of claim 2 and further comprising:
a timing controller coupled to provide a trigger to the pulse generator and to adjust the delay provided by the delay line.

5. The system of claim 4 wherein the timing controller provides the trigger and adjusts the delay as a function of a varied speed of the simulated device.

6. The system of claim 5 wherein the pulse generator generates the at least two pulses as a function of torque of the simulated device.

7. The system of claim 1 wherein the simulated device is an engine and the at least two pulses includes N pulses wherein N corresponds to the number of cylinders of the engine to be simulated.

8. The system of claim 1 wherein the simulated device is a helicopter and the at least two pulses comprises N pulses wherein N corresponds to the number of rotors of the helicopter to be simulated.

9. The system of claim 1 further comprising at least one additional sound component generator to provide an additive sound corresponding to at least one further component of a vehicle exhaust system.

10. The system of claim 9 wherein the at least one additional sound component generator generates sound corresponding to a pipe of the vehicle exhaust system.

11. The system of claim 1 wherein the pulse train is a simulated aural pulse train corresponding to sounds produced by one of a truck using reciprocating piston engines, a tank, a rotary wing aircraft, and an automatic gun.

12. The system of claim 1 and further comprising an additive sound generator coupled to generate an additive sound comprising one of tire noise, ground rumble, brakes, air intake, pneumatics, fan belts, an engine turbo charger, and frame and body part rattle.

13. A method comprising the steps of:
generating a repeating pulse train including at least two pulses per cycle of the pulse train;
delaying the at least two pulses in the pulse train by a length of the cycle of the pulse train;
attenuating the delayed at least two pulses to create chaotic inducing components;
summing the chaotic inducing components with at least two pulses from a succeeding cycle of the pulse train
to produce an output representative of sound made by a simulated device.

14. The method of claim 13 and further comprising the step of controlling the generating step and the delaying step based on user interaction with the simulated device.

15. The method of claim 13 and further comprising the step of repeating the generating, delaying, attenuating, and summing steps over multiple cycles.

16. The method of claim 15 wherein the output representative of the sound corresponds to pistons of an engine, and wherein the method further comprises the step of adding sounds corresponding to exhaust system components to the output representative of the sound.

17. The method of claim 16 and further comprising the step of adding auxiliary sounds to the output representative of the sound.

18. The method of claim 16 and further comprising the step of modifying the output representative of the pulse train by a three dimensional space model.

19. The method of claim 15 wherein the output representative of the sound corresponds to sounds of a rotary wing aircraft.

20. The method of claim 15 wherein the output representative of sounds corresponding to sounds produced by one of a truck using reciprocating piston engines, a tank, rotary wing aircraft and automatic gun.

21. A computer readable storage device having instructions for causing a computer system to execute a method, the method comprising the steps of:
generating a repeating pulse train including at least two pulses per cycle;
delaying the at least two pulses in the pulse train by a length of the cycle of the pulse train;
attenuating the delayed pulses to create chaotic components;
summing the chaotic components with at least two pulses from a succeeding cycle of the pulse train; and
repeating the generating, delaying, attenuating and summing over multiple cycles of the pulse train to produce an output representative of a sound of a simulated device.

22. The computer readable storage device of claim 21 wherein the at least two pulses comprises N pulses wherein N corresponds to one of the number of rotors of a helicopter, the number of cylinders of an engine and the number of barrels of a gun.

23. The computer readable storage device of claim 21 and further comprising the step of controlling the generating step and the delaying step based on user interaction with the simulated device.
